(19) United States
(12) Patent Application Publication
(10) Pub. No.: US 2008/0247501 A1
(43) Pub. Date: Oct. 9, 2008

(54) FIFO REGISTER UNIT AND METHOD THEREOF

(75) Inventor: Guangyu Zhang, Taipei (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: VIA TECHNOLOGIES, INC., Taipei (TW)

(21) Appl. No.: 12/036,370

(22) Filed: Feb. 25, 2008

(30) Foreign Application Priority Data
Apr. 6, 2007 (CN) 200710096753.7

(51) Int. Cl. G11C 19/00

(52) U.S. Cl. 377/70

(57) ABSTRACT

A FIFO register unit is provided, comprising a first sub-register unit, an input multiplexer and an output multiplexer. The first sub-register unit comprises a first register, a second register and a third register. The first register comprises an input terminal to receive a first input data. The second register receives data from the first register. The third register receives the first input data from the input terminal, data from the first register or data from the second register and determines one of them to output as a first output data.

### BACKGROUND OF THE INVENTION

1. Field of the Invention

The invention relates to a FIFO (First In First Out) register unit, and in particular relates to a high speed and low loading FIFO register unit.

2. Description of the Related Art

FIG. 1 shows a schematic diagram of a FIFO buffer unit 100 with four inputs and four outputs. The FIFO buffer unit 100 with four inputs and four outputs can be used between a central processing unit (CPU) and a north bridge for data communication. The FIFO buffer unit 100 comprises four-to-one multiplexers (MUX) 111, 112, 113, 114, 141, 142, 143 and 144, FIFO registers 121, 122, 123 and 124 and sixteen-to-one multiplexers 131, 132, 133 and 134. The FIFO registers 121, 122, 123 and 124 are registers for storing sixteen data in 32 bits.

Inputting data Data0, Data1, Data2 and Data3 are stored in corresponding position of the FIFO registers 121, 122, 123 and 124 through four-to-one multiplexers 111, 112, 113 and 114. Sixteen-to-one multiplexers 131, 132, 133 and 134 receive data from FIFO registers 121, 122, 123 and 124 to output to four-to-one multiplexers 141, 142, 143 and 144.

As known from FIG. 1, four-to-one multiplexers 111, 112, 113 and 114 are required enough driving capacity to drive FIFO registers 121, 122, 123 and 124 which can store sixteen data in 32 bits. Since four-to-one multiplexers 111, 112, 113 and 114 need bigger driving circuits, the four-to-one multiplexers are more complicated and need more transmitting gates. The more transmitting gates of the four-to-one multiplexers have, the slower the transmitting speed.

### BRIEF SUMMARY OF THE INVENTION

A detailed description is given in the following embodiments with reference to the accompanying drawings.

An embodiment of a FIFO register unit is provided. A FIFO register unit comprises a first sub-register unit. The first sub-register unit comprises a first register, a second register and a third register. The first register comprises an input terminal to receive an input data. The second register receives data from the first register. The third register receives the input data from the input terminal, data from the first register or data from the second register and determines one of them to output as an output data.

Another embodiment of a FIFO register is provided. A FIFO register unit, comprises a plurality of input multiplexer, a plurality of output multiplexer, and a plurality of sub-register units coupled between the corresponding input multiplexers and output multiplexers respectively. Each of the sub-register comprises a first register, a second register and a third register. The first register comprises an input terminal coupled to the corresponding input multiplexer to receive an input data. The second register receives data from the first register. The third register selectively receives the input data from the input terminal, data from the first register or data from the second register and outputting an output data to the corresponding output multiplexer.

Another embodiment of a FIFO registering method is provided. The method comprises: determining data storing status of a first register, a second register and a third register of a first sub-register unit; storing an input data into the third register when the first register, the second register and the third register are empty; and storing the input data into the first register when the third register is full and the first register is empty.

### BRIEF DESCRIPTION OF THE DRAWINGS

The invention can be more fully understood by reading the subsequent detailed description and examples with references made to the accompanying drawings, wherein:

FIG. 1 shows a schematic diagram of a FIFO buffer unit with four inputs and four outputs; and

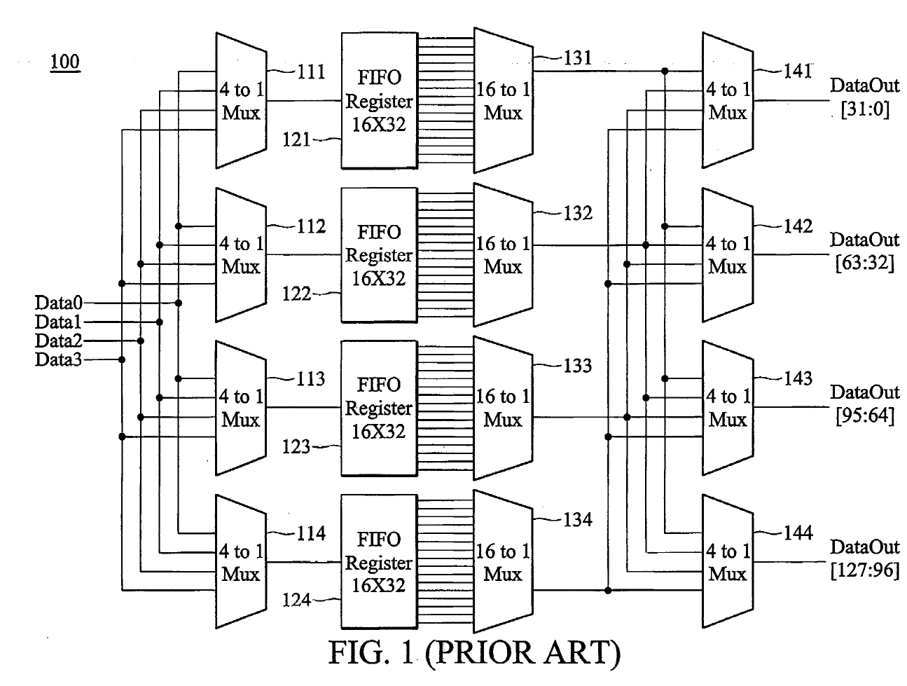

FIG. 2 is a schematic diagram of a FIFO register unit 200 according to an embodiment of the invention;

FIG. 3 is a sub-register unit according to an embodiment of the invention;

FIG. 4 is a flow chart of a first in first out registering method according to another embodiment of the invention;

FIG. 5 is a flow chart of a first in first out registering method according to another embodiment of the invention; and

FIG. 6 is a flow chart of a first in first out registering method according to another embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The main concept of present invention is to design a FIFO (first in first out) register unit, which is composed of plural register groups for receiving or outputting several data simultaneously. Each register group is further divided into multi levels, for example, L1, L2 and L3. In order to reduce the data loading from input port to registers and output delay from register to output port, the received data is pushed into L1 or L3 according to storage status of L1 to L3, and the output data is popped out from L3 directly.

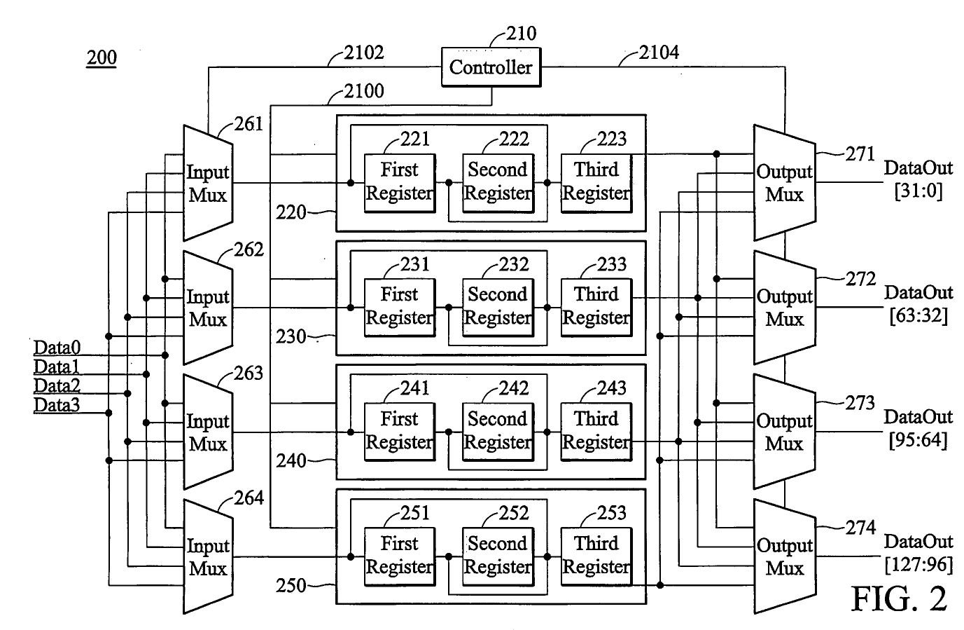

FIG. 2 is a schematic diagram of a FIFO register unit 200 according to an embodiment of the invention. FIFO register unit 200 comprises controller 210, input multiplexers (MUX) 261, 262, 263 and 264, output multiplexers 271, 272, 273 and 274 and sub-register units 220, 230, 240 and 250. The sub-register units 220, 230, 240 and 250 respectively comprises the first registers 221, 231, 241 and 251, the second registers 222, 232, 242 and 252 and the third registers 223, 233, 243 and 253. The first, second and third registers are also respectively called L1, L2 and L3 registers. In addition, output terminals of the input multiplexers (Mux) 261, 262, 263 and 264 are coupled to input terminals of the first registers 221, 231, 241 and 251.

According to an embodiment of the invention, data Data0, Data1, Data2 and Data3 are 32 bit data, one double word (DW). The size of the first registers 221, 231, 241 and 251 is one double word (DW) equaling to the length of data received by the sub-register units 220, 230, 240 and 250 within a single transmitting cycle. The size of the third registers 223, 233, 243 and 253 equals to the size of data outputted from the sub-register units 220, 230, 240 and 250 within a single transmitting cycle, one double word too. The size of second registers 222, 232, 242 and 252 is assumed to be fourteen double words (DW).

As known by persons skilled in the art, controller 210 generates a control signal 2100 to control sub-register units 220, 230, 240 and 250, an input control signal 2102 and an output control signal 2104 according to register values Psh, Pop and PopLen. According to an embodiment of the invention, when the register value Psh is 4′b0000, the controller 210 sends the input control signal 2102 to the input multiplexers 261, 262, 263 and 264 to stop transmitting data. When the register value Psh is 4′b0001, the controller 210 controls the input multiplexers 261, 262, 263 and 264 to transmit data Data0. When the register value Psh is 4′b0011, the controller 210 controls the input multiplexers 261, 262, 263 and 264 to transmit data Data0 and Data1. When the register value Psh is 4′b0111, the controller 210 controls the input multiplexers 261, 262, 263 and 264 to transmit data Data0, Data1 and Data2. When the register value Psh is 4′b1111, the controller 210 controls the input multiplexers 261, 262, 263 and 264 to transmit data Data0, Data1, Data2 and Data3. The sub-register units 220, 230, 240 and 250 store data in the first registers 221, 231, 241 and 251 or the third registers 223, 233, 243 and 253 according to the register value Psh.

The third registers 223, 233, 243 and 253 output data according to the register values Pop and PopLen. According to an embodiment of the invention, when the register value Pop is “1” and the register value PopLen is 2′b00, the controller 210 sends output control signal 2104 to the output multiplexer 271 to output data Data0ut [31:0]. When the register value Pop is “1” and the register value PopLen is 2′b01, the controller 210 controls the output multiplexers 271 and 272 to respectively output data Data0ut [31:0] and Data0ut [63:32]. When the register value Pop is “1” and the register value PopLen is 2′b10, the controller 210 controls the output multiplexers 271, 272 and 273 to respectively output data Data0ut [31:0], Data0ut [63:32] and Data0ut [95:64]. When the register value Pop is “1” and the register value PopLen is 2′b11, the controller 210 controls the output multiplexers 271, 272, 273 and 274 to respectively output data Data0ut [31:0], Data0ut [63:32], Data0ut [95:64] and Data0ut [127:96]. The FIFO register unit 200 outputs one double word at least or outputs four double words at most.

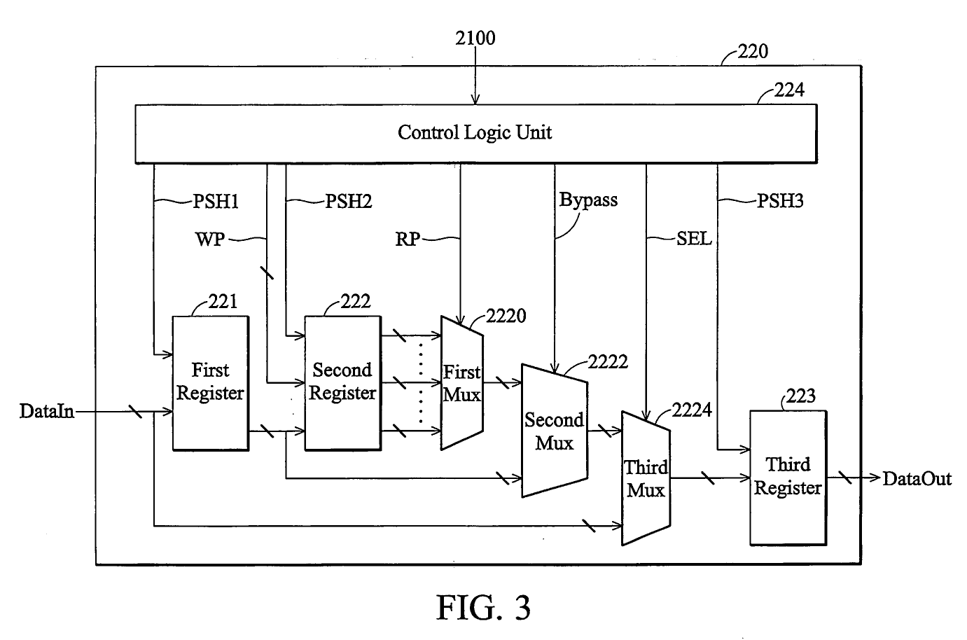

According to an embodiment of the invention, since sub-register units 220, 230, 240 and 250 are the same, only the sub-register unit 220 will be explained in detail as an example. As shown in FIG. 3, the sub-register unit 220 comprises the multiplexers 2220, 2222 and 2224 and a control logic unit 224. The multiplexers 2220, 2222 and 2224 are coupled between the second register 222 and the third register 223. The control logic unit 224 gets the data storing status of the first, second and third registers 221, 222 and 223 according to the control signal 2100. The control logic unit 224 generates a first storing signal PSH1, a second storing signal PSH2, a third storing signal PSH3, a selecting signal SEL, a writing pointer WP, an output pointer RP and an bypass signal Bypass for controlling the first, second and third registers 221, 222 and 223 and the multiplexers 2220, 2222 and 2224. The first register 221 determines whether to store data Data1into the sub-register unit 220 or not according to the first storing signal PSH1. The second register 222 determines whether to receive the data from the first register 221 or not according to the second storing signal PSH2 and stores the receiving data into the pointing position according to the writing pointer WP. In this embodiment of the invention, since the second register 222 can store fourteen double words, the first multiplexer 2220 is a fourteen-to-one multiplexer. The first multiplexer 2220 receives data form the second register 222 and selects data to output according to the output pointer RP. The second multiplexer 2222 comprises two input terminals to respectively receive the data from the first multiplexer 2220 and from the first register 221. When the bypass signal Bypass enables, the second multiplexer 2222 outputs data from the first register 221. The third multiplexer 2224 receives data Data1n and data from the second multiplexer 2222 and selects data to output according to the selecting signal SEL. For example, when the selecting signal SEL enables, the third multiplexer 2224 outputs data Data1n to the third register 223. When the selecting signal SEL disables, the third multiplexer 2224 outputs data from the second multiplexer 2222 to the third register 223. In this embodiment of the invention, only when the third register 223 is empty and needs to store data, the third storing signal PSH3 will enable. When the third storing signal PSH3 enables, the third register 223 receives and stores data from the third multiplexer 2224. From the above description, it is obvious that the sub-register unit 220 receives data Data1n and stores data directly into the first register 221 or the third register 223 through the third multiplexer 2224. Further, the second register 222 can receive data from the first register 221 and transmit data to the third register 223 through the multiplexers 2220, 2222 and 2224.

Please refer to FIGS. 3-6, using sub-register unit 220 as an example, the following description discloses how to process the data Data1n, the data Data0, Data1, Data2 or Data3 and how the first, second and third registers transmit data according to the signals of the control logic unit 224.

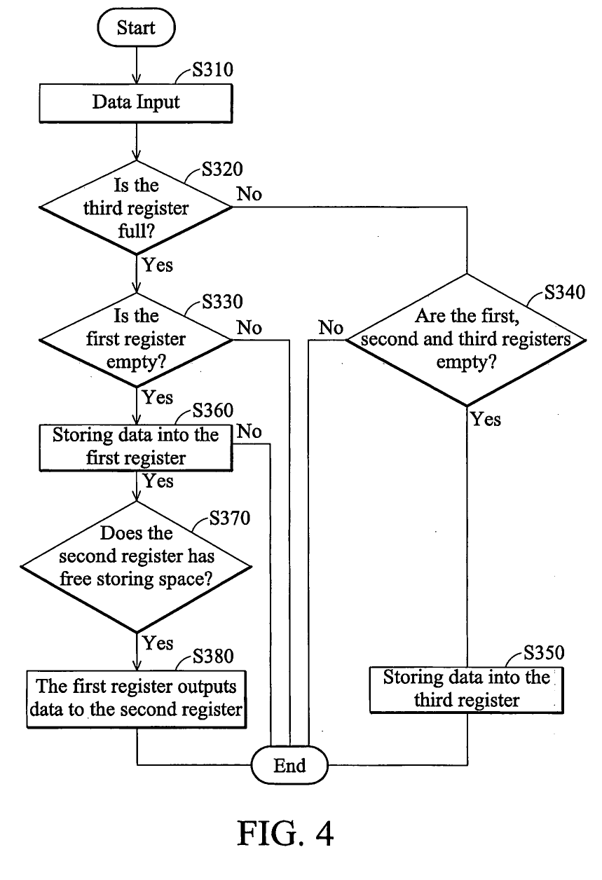

FIG. 4 is a flow chart of a first in first out registering method according to another embodiment of the invention. Please refer to the sub-register unit 220 of FIG. 3, according to an embodiment of the invention, when the registering value Psh is “1”, the sub-register unit 220 receives data (Step S310). The controller 224 determines whether the third register 223 is full or not (Step S320). If the third register 223 is full, it determines whether the first register 221 is full or not (Step S330). If yes, the first storing signal PSH1 enables and the sub-register unit 220 stores data into the first register 221 (Step S360). If the first and third registers 221 and 223 are both full, the method ends. If the third register 223 is not full, the control logic unit 224 determines whether the first, second and third registers 221, 222, 223 are empty (Step S340). If the first and third registers 221 and 223 are empty, the selecting signal SEL and the third storing signal PSH3 are enabled and the data Data1n is stored into the third register 223 through the third multiplexer 2224 (Step S350). After storing data into the first register 221 (Step S360), the controller 224 determines whether the second register 222 has free storage space (Step S370). If the second register 222 has free storage space, the second storing signal PSH2 enables the second register 222 to receive and store the data from the first register 221 (Step S380).

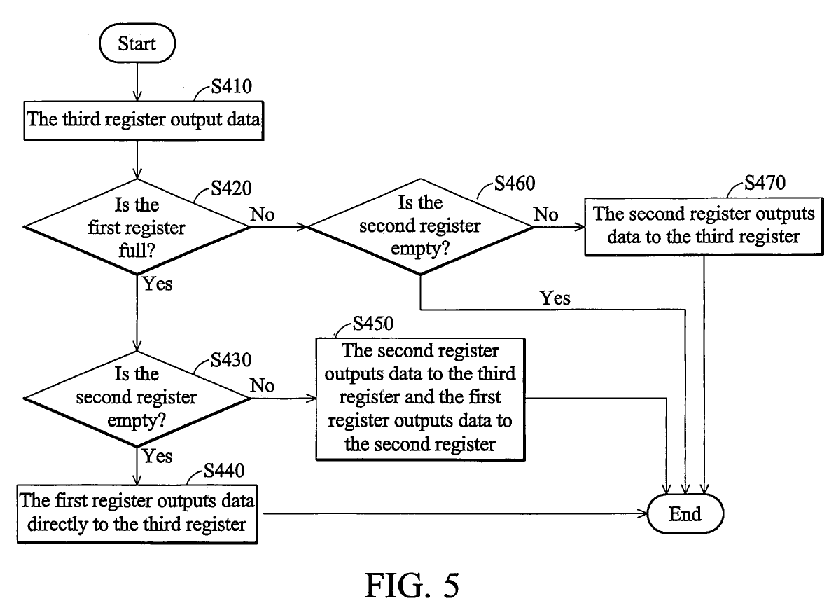

FIG. 5 is a flow chart of a first in first out registering method according to another embodiment of the invention. Please refer to the sub-register unit 220 of FIG. 3, according to an embodiment of the invention, when the registering value Pop is “1”, the control logic unit 224 of the sub-register unit 220 controls the third register 223 to output data (Step S410). Next, the control logic unit 224 determines whether the first register 221 is full or not (Step S420). If the first register 221 is full, it determines whether the second register 222 is empty or not (Step S430). If the first register 221 is full and the second register 222 is empty, the control logic unit 224 enables the bypass signal Bypass and the third storing signal PSH3 and disables the selecting signal SEL so that the first register 221 sends the data directly to the third register 223 (Step S440). If the first register 221 is full and the second register 222 is not empty, the second and third storing signals PSH2 and PSH3 enable and the bypass signal Bypass disables so that the third register 223 receives the data from the second register 222 and the second register 222 receives the data from the first register 221 (Step S450). If the first register 221 is not full (the first register 221 is empty, Step S420), it is determined whether the second register 222 is an empty register (Step S460). If the second register 222 is empty, the bypass signal Bypass and the selecting signal SEL are disabled while the third storing signal PSH3 is enabled, so that the second register 222 sends data to the third register 223 (Step S470).

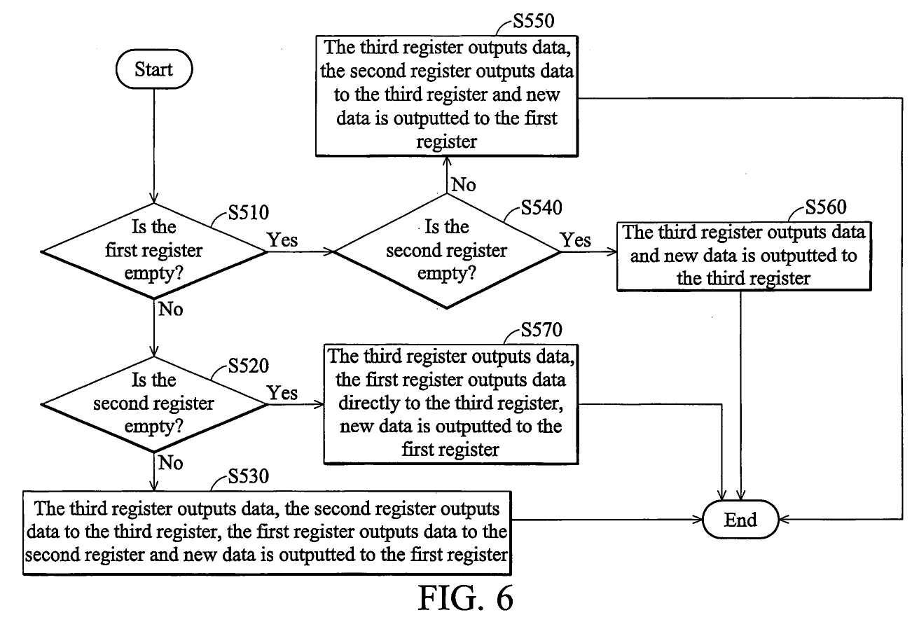

FIG. 6 is a flow chart of a first in first out registering method according to another embodiment of the invention. Please refer to the sub-register unit 220 of FIG. 3, according to an embodiment of the invention, when the register values Pop and Psh are “1”, the control logic unit 224 decides how to transmit data between the first, second and third registers 221, 222 and 223 according to the data storing status of the first register 221 and the second register 222. Specifically, if the first register 221 is not empty (Step S510) and the second register 222 is not empty (Step S520), the control logic unit 224 controls the third register 223 to output data. Simultaneously, the bypass signal Bypass and the selecting signal SEL are disabled and the third storing signal PSH3 is enabled so that the second register 222 outputs data to the third register 223. The second storing signal PSH2 is enabled so that the first register 221 outputs data to the second register 222. The first storing signal PSH1 is enabled so that new data is stored into the first register 221 (Step S530). If the first register 221 is empty (Step S510) and the second register 222 is empty (Step S540), the control logic unit 224 controls the third register 223 to output data and enables the selecting signal SEL and the third storing signal, so as to store new data in the third register 223 (Step S560). If the first register 221 is empty and the second register 222 is not empty (Step S540), the third register 223 outputs data, the selecting signal SEL and the bypass signal Bypass are disabled and the third storing signal PSH3 is enabled, so that the second register 222 outputs data to the third register 223 and the first storing signal PSH1 enables the first register 221 to store new data (Step S550). If the first register 221 is not empty (Step S510) and the second register 222 is empty (Step S520), the third register 223 outputs data, the bypass signal Bypass and the third storing signal PSH3 are enabled and the selecting signal SEL are disabled, so that the first register 221 directly outputs data to the third register 223, and the first storing signal PSH1 is enabled so that the first register 221 stores new data (Step S570).

Using the above FIFO register unit 200 with the FIFO registering method, the input multiplexers 261, 262, 263 and 264 only respectively drive the first registers 221, 231, 241 and 251 and the third registers 223, 233, 243 and 253, that is to say, the data is only stored into the first registers 221, 231, 241 and 251 and the third registers 223, 233, 243 and 253. Thus, the input multiplexers 261, 262, 263 and 264 do not need large driving capacity and reduce the complexity and the amount of transmitting gates. Because of less transmitting gates, the layout size of the input multiplexers 261, 262, 263 and 264 can be reduced and the transmitting speed can be increased. With regard to outputting data, because of accessing data only from the third registers 223, 233, 243 and 253, the speed of outputting data is faster.

While the invention has been described by way of example and in terms of preferred embodiment, it is to be understood that the invention is not limited to thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A FIFO register unit, comprising:
a first register comprising an input terminal to receive an input data;
a second register receiving data from the first register; and
a third register selectively receiving the first input data from the input terminal, data from the first register or data from the second register and outputting an output data.

2. The FIFO register unit as claimed in claim 1, wherein in response to empty of the first register, the second register and the third register, the input data is stored into the third register.

3. The FIFO register unit as claimed in claim 1, wherein in response of that the first register is empty and the third register is full, the input data is stored into the first register.

4. The FIFO register unit as claimed in claim 1, wherein in response of that the second register has free storage space and the first register and the second register are full, the first register outputs the data to the second register.

5. The FIFO register unit as claimed in claim 1, wherein in response of that the third register outputs the output data, the first register is full and the second register is not empty, the third register receives the data from the second register and the second register receives the data from the first register.

6. The FIFO register unit as claimed in claim 1, wherein in response of that the third register outputs the output data, the first register is empty and the second register is not empty, the third register receives the data from the second register.

7. The FIFO register unit as claimed in claim 1, wherein in response of that the third register outputs the output data, the first register is full and the second register is empty, the first register directly outputs the data to the third register.

8. The FIFO register unit as claimed in claim 1, wherein the size of the third register equals to the size of the output data, and the size of the first register equals to the size of the output data.

9. The FIFO register unit as claimed in claim 1, further comprising:
a first multiplexer selectively outputting one data from the second register according to an output pointer;
a second multiplexer receiving the data from the first register and the data from the first multiplexer and outputting one of them according to an bypass signal; and
a third multiplexer receiving the input data and the data from the second multiplexer and outputting one of them to the third register according to a selecting signal.

10. The FIFO register unit as claimed in claim 9, further comprising a control logic unit determining status of the first register, the second register and the third register according to a control signal, wherein the control logic unit further generating the output pointer, the bypass signal and the selecting signal according to the status of the first, the second and the third register.

11. The FIFO register unit as claimed in claim 10, wherein the control logic unit bases on the control signal to generate:
a first storing signal controlling the first register to receive the input data or not;
a second storing signal controlling the second register to receive the data from the first register or not; and
a third storing signal controlling the third register to receive the input data, the data from the first register or the data from the second register.

12. A FIFO register unit, comprising:
a plurality of input multiplexer;
a plurality of output multiplexer; and
a plurality of sub-register units coupled between the plurality of input multiplexers and output multiplexers,
wherein each of the sub-register comprising:
a first register comprising an input terminal coupled to the corresponding input multiplexer to receive an input data;
a second register receiving data from the first register; and
a third register selectively receiving the input data from the input terminal, data from the first register or data from the second register and outputting an output data to the corresponding output multiplexer.

13. The FIFO register unit as claimed in claim 12, wherein in response to empty of the first register, the second register and the third register, the input data is stored into the third register;
wherein in response of that the first register is empty and the third register is full, the input data is stored into the first register;
wherein in response of that the second register has free storage space and the first register and the second register are full, the first register outputs the data to the second register;
wherein in response of that the third register outputs the output data, the first register is full and the second register is not empty, the third register receives the data from the second register and the second register receives the data from the first register;
wherein in response of that the third register outputs the output data, the first register is empty and the second register is not empty, the third register receives the data from the second register;
wherein in response of that the third register outputs the output data, the first register is full and the second register is empty, the first register directly outputs the data to the third register; and
wherein the size of the third register equals to the size of the output data, and the size of the first register equals to the size of the output data.

14. A FIFO registering method, comprising:
determining data storing status of a first register, a second register and a third register;
storing an input data into the third register when the first register, the second register and the third register are empty; and
storing the input data into the first register when the third register is full and the first register is empty.

15. The FIFO registering method as claimed in claim 14, wherein in response of that the second register has free storage space and the first register and the second register are full, the first register outputs the data to the second register.

16. The FIFO registering method as claimed in claim 14, further comprising directly outputting data to be stored in the third register.

17. The FIFO registering method as claimed in claim 14, further comprising in response of that the third register outputs the data and the first register is full and the second register is not empty, data of the second register is stored into the third register and data of the first register is stored into the second register.

18. The FIFO registering method as claimed in claim 14, further comprising when the third register outputs the data and the first register is empty and the second register is not empty, data of the second register is transmitted to the third register.

19. The FIFO registering method as claimed in claim 14, further comprising when the third register outputs the data and the first register is full and the second register is empty, data of the first register is stored into the third register.

20. The FIFO registering method as claimed in claim 14, wherein the second register receives data from the first register, and the third register receives data from the second register or the first register.
